(19) United States
(12) Patent Application Publication
(10) Pub. No.: US 2013/0073172 A1
(43) Pub. Date: Mar. 21, 2013

(54) DETECTION SYSTEM AND METHOD

(71) Applicants: Bret Dwayne Worden, Erie, PA (US); Matthew John Malone, Lawrence Park, PA (US); Milan Karunaratne, Lawrence Park, PA (US)

(72) Inventors: Bret Dwayne Worden, Erie, PA (US); Matthew John Malone, Lawrence Park, PA (US); Milan Karunaratne, Lawrence Park, PA (US)

(21) Appl. No.: 13/233,754

(22) Filed: Sep. 15, 2011

(51) Int. Cl. F02D 23/00; G01M 15/04; G01R 27/08; F04D 29/00; G02B 6/00

(52) U.S. Cl. 701/101; 415/118; 385/13; 324/693; 73/114.31; 73/865.8

(57) ABSTRACT

A detector (50) including a sensor (52) configured to detect entry of a portion of a wheel (20) into a portion of a clearance gap (37) and thereby to signify that the wheel (20) has deviated from the intended wheel path.

### BACKGROUND

1. Technical Field

The invention includes embodiments that relate to a detection system for a rotating machine and associated methods.

2. Discussion of Art

Deviation of the compressor wheel or fan resulting from foreign object damage, rotating unbalance, or other causes may lead to contact between the compressor wheel and the shroud, sometimes referred to as shroud rub. Shroud rub often results in bearing instability in the turbo charger, which has long been a top contributor of turbo machinery failure.

It may sometimes be desirable to have a detector that detects or predicts the onset of contact or rub between the compressor wheel and the shroud.

### BRIEF DESCRIPTION

In an embodiment, a detector includes a sensor configured to detect entry of a portion of a wheel into a portion of a clearance gap and thereby to signify that the wheel has deviated from an intended wheel path.

An embodiment includes a method that includes detecting a change in at least one of a voltage and a current through a circuit caused in response to an entry of a portion of a wheel within a clearance gap.

Another embodiment includes a detector kit including a detector circuit including a wire loop connectable to a power source, a resistor, and a data acquisition system.

In another embodiment, a rotating system includes a turbo charger including a wheel mounted on a shaft. The wheel has at least one blade. A shroud at least partially encloses the wheel, where a clearance gap is defined between the at least one blade and an inner surface of the shroud. The rotating system further includes a sensor configured to detect entry of a portion of the wheel into a portion of the clearance gap.

### BRIEF DESCRIPTION OF THE DRAWINGS

Reference is made to the accompanying drawings in which particular embodiments of the invention are illustrated as described in more detail in the description below, in which:

FIG. 1 is a cross section of a turbo charger in accordance with an embodiment of the invention;

FIG. 2 is a schematic cross section of a rotating system according to an embodiment of the invention;

FIG. 3 is a schematic view of a detector according to an embodiment of the invention;

FIG. 4 is a schematic cross section of a rotating system in accordance with an embodiment of the invention; and

FIG. 5 is a perspective view of a rail vehicle with an engine and turbo charger schematically shown.

### DETAILED DESCRIPTION

Embodiments of the subject matter disclosed herein relate to systems and methods for detecting conditions in rotating systems including a turbo charger used in connection with an engine. The rotating system may be included in a stationary application or in a vehicle, such as a locomotive system. Other suitable types of vehicles may include on-highway vehicles, off-highway vehicles, mining equipment, aircraft, and marine vessels. Other embodiments of the invention may be used for stationary engines such as wind turbines or power generators. The engine may be a diesel engine, or may combust another fuel or combination of fuels.

In one embodiment, a rotating system can include a shaft, a rotating component coupled to the shaft, and a housing that at least partially encompasses the rotating component. The shaft can cause the rotating component to rotate within the housing. A clearance gap is the space between the rotating component and the housing inner surface. A “wheel” is any rotating component of any shape or dimension including but not limited to a fan blade, a hub, a gear, a compressor wheel, or a drive wheel. A “shaft” is a member that imparts rotation to the wheel, and may have any shape, dimension or cross-section. A “shroud,” as used herein, is any housing that at least partially encompasses a wheel creating a gap between at least a portion of the wheel and the shroud. An “intended wheel path” is the path of rotation through which the wheel travels when operating under normal circumstances, this path effectively is defined by the cross-section of the wheel rotated about an axis of rotation. A “clearance gap” is the gap or space formed between the intended wheel path and the shroud. Use of the terms, fiber, filament, or wire are not to be considered limiting in terms of their dimension, shape or cross-section.

Embodiments of the invention relate to a system for detecting a condition within a rotating system such as a turbo charger. Other rotating systems may include gearboxes, turbines, and the like. The condition may be one or more of an imbalance, foreign object damage or other irregularity. The condition may cause a gear, a fan, wheel, such as a compressor wheel or drive wheel to deviate from its intended wheel path. The condition includes deviations that lead to or cause contact between the fan or wheel and the shroud. As used herein, these conditions will be collectively referred to as a condition or rub.

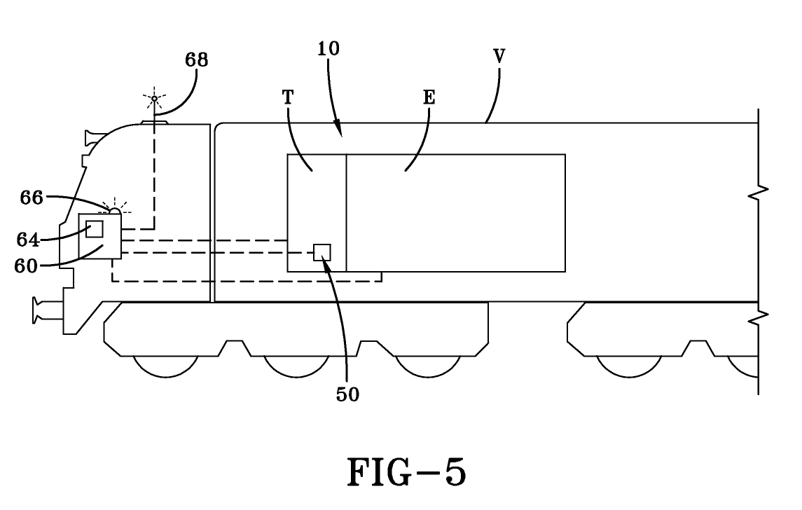

An embodiment of the invention includes rotating system 10 that includes a turbo charger T. The rotating system may form part of a power generation system or vehicle V. The rotating system, therefore, may include an engine or generator connected to the turbo charger. FIG. 5 depicts a turbo charger T connected to an engine E used to power the vehicle V.

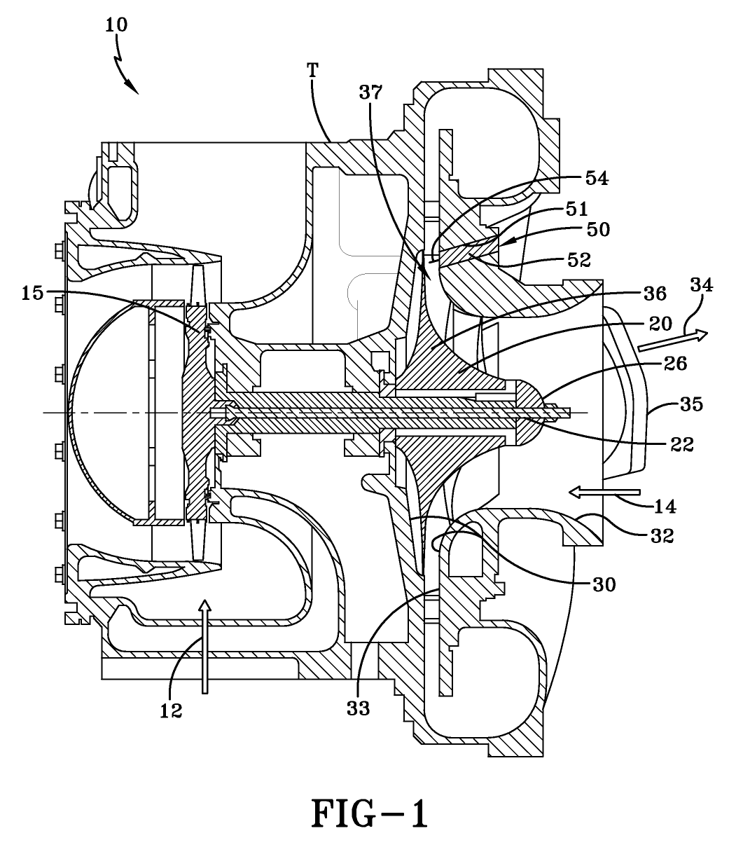

As best shown in FIG. 1, the turbo charger T includes a rotatable shaft 22 with a compressor wheel 20 mounted on the shaft 22. The shaft 22 is driven by a drive wheel 15, also referred to as a turbine wheel, connected to the shaft 22, such that, rotation of the drive wheel causes rotation of the shaft. The drive wheel is in fluid communication with a pressurized flow 12, for example, of exhaust gas from an engine or charged air. One or more blades or vanes on the drive wheel are driven by the pressurized flow and used to drive the shaft and rotate the compressor wheel. The terms blade and vane will be used interchangeably and should not be considered limiting.

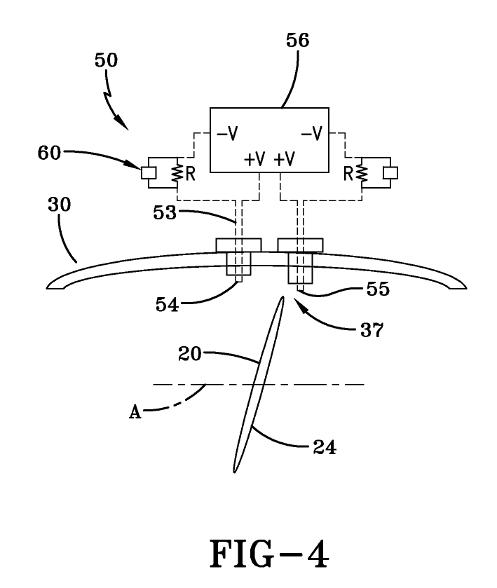

The compressor wheel 20 includes at least one vane or fan blade 24 mounted on a hub 26. The hub 26 is connected to the shaft, which is rotatably supported by suitable bearings. A shroud 30 at least partially encompasses compressor wheel 20 and defines an opening or compressor inlet 32 through which the compressor wheel draws air into the shroud. In the example shown, the shroud defines a central inlet that is coaxial with the compressor wheel 20. The inlet 32 exposes a center portion of the compressor wheel. Fluid, such as air, is drawn through the inlet 32 and compressed by rotation of the compressor wheel 20 within the shroud 30. With reference to FIG. 4, compressed air exits the shroud at a second opening or compressor discharge 35. In the example shown, compressed air 34 exiting the discharge is directed to an engine E for use in combustion. The pressurized fluid from the compressor wheel is directed from the turbo charger for use in power generation, creation of a motive force, or to boost performance of an engine. In the example shown in FIG. 5, the pressurized air from the compressor wheel exits the shroud at a compressor discharge 35 and is supplied to the engine for use in combustion.

With reference to FIG. 2, the inner surface 33 of shroud 30 is spaced outward from the compressor wheel defining a clearance gap 37 between the shroud 30 and the compressor wheel 20. The compressor wheel rotates about a central axis A. The cross-section 36 (FIG. 1) of compressor wheel 20 defines an intended wheel path as it rotates under normal operating conditions. Accordingly, the clearance gap between the shroud and the compressor wheel lies outward of the compressor wheel as it rotates along its intended wheel path. An imbalance in the compressor wheel may cause the compressor wheel to deviate from its intended wheel path and enter the clearance gap between the compressor wheel and the shroud. A sufficient deviation will cause the compressor wheel to contact the shroud.

Conditions including compressor wheel damage, shroud rub, and resulting bearing instability in a turbo charger have long been a top contributor of turbo machinery failure. Turbo charger failure is undesirable. In some instances, turbo charger conditions lead to damage to downstream components within a turbo machine or engine air intake system components.

To reduce the chance of turbo charger failure and engine shutdown, a detector 50 is provided. The detector detects deviation of the compressor wheel 20 from its intended wheel path by detecting the presence of the compressor wheel in the clearance gap 37 between the compressor wheel and the shroud 30. The detector 50 includes a sensor 52 that monitors at least a portion of the clearance and may provide a signal upon detecting the presence of the compressor wheel or other object within the clearance.

The sensor is inserted in an aperture 51 that places the sensor in a position to detect deviations in the travel of the wheel that cause it to enter the clearance gap. The aperture may be formed at the time of manufacture or added to the rotating system when retrofitting the system with a detector system. In the example shown, the aperture is formed in the shroud surrounding the compressor wheel. This location is not limiting.

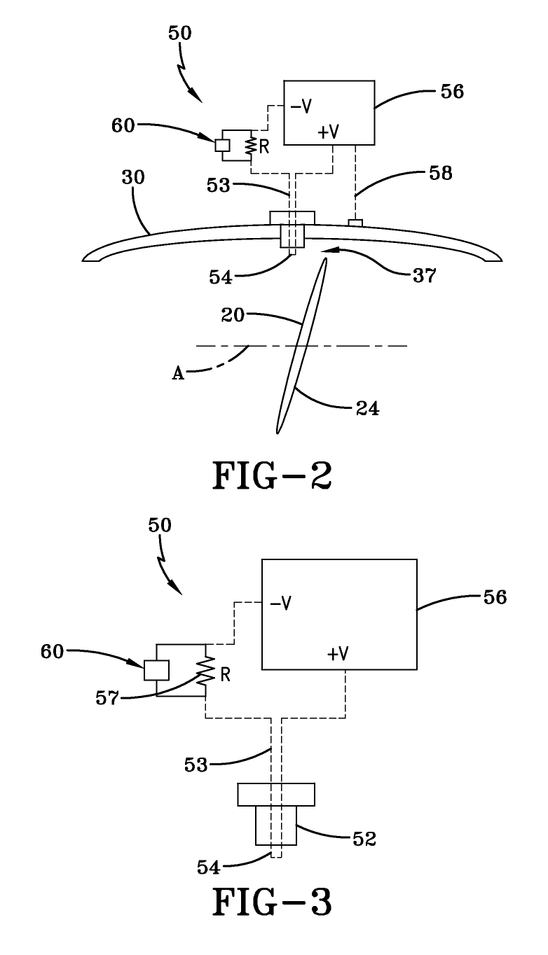

With reference to FIGS. 2 and 3, an embodiment of a detector 50 is shown where the sensor includes a sacrificial member 53, such as a optical fiber or wire loop that has a portion 54 extending into the clearance. Proximity of the wheel to the sensor, displacement of the sensor, or contact with the sensor by the wheel or a foreign object is sensed as a change in at least one of the voltage and current through the wire loop, or a change in the intensity, phase, polarization, wavelength, or transmission time of light in the optical fiber.

According to one embodiment, the sacrificial member is a conductive wire loop. The wire loop is connected to a power source 56. An in-line resistor 57 is located between the power source and the wire loop. In an alternate embodiment, power source 56 is connected to the chassis of a vehicle or to the shroud by a lead 58 (FIG. 2). This lead is coupled electrically to the output voltage supply to the wire loop 53. By connecting the power source to a ground, such as, the chassis of the rotating machine or shroud, the passage of each fan blade past the wire loop creates a displacement current. When the compressor wheel is rotating on its intended wheel path, the displacement current will be sensed at regular intervals corresponding to the space between blades. A deviation in the path of the compressor wheel or actual rub would change the signature of the displacement current due to the increased proximity of the blade(s) to the sensor 52.

A data acquisition system 59 is connected to monitor the signal generated by sensor 52. Alternatively, the sensor is connected to a controller 60, which may be an existing controller, when retrofitting the detector 50 to an existing rotating system. For example, as shown in FIG. 5, detector 50 is connected to a controller 60 within a vehicle V.

In the embodiment shown, the signal from sensor 52 includes a current signal or a voltage drop across the resistor. Contact between the compressor wheel and the wire loop is sensed by the data acquisition system as a voltage loss. For example, during healthy operation of the compression wheel, the data acquisition system sees a voltage at the resistor. If the wire loop is sheared by the blade, the circuit between the power source and the resistor is broken causing the voltage to drop to zero volts. The zero volt condition indicates an unhealthy condition where rub has occurred or is likely to occur. Contact between the compressor wheel and the wire also is sensed by data acquisition system as a voltage drop. When a lead 58 connects the power source to the chassis or shroud 30, the passage of the blade 24 of the compressor wheel past wire loop causes a capacitive increase within wire loop sensed as a displacement current by data acquisition system 59.

Any deviation of the compressor wheel from its intended wheel path detected by the sensor indicates a condition within the turbo charger. Upon detecting such a deviation, data acquisition system or an associated controller 60 takes remedial action. Remedial action includes logging the deviation for review by maintenance personnel. To that end, data acquisition system or controller includes a memory 64 in which deviation information is stored. Deviation information logged in memory may include the speed of the compressor wheel and the time at which the deviation occurred. Additional information logged may include the operating speed of the engine or generator to which the turbo charger is connected, power output level, and operating temperature of the turbo charger. Remedial action may also include alerting an operator or other person or machine monitoring the system by activating a warning indicator 66. Warning indicator may in the same location as the detector and or located remotely from the detector. As shown in FIG. 5, the warning indicator is located in the cab of the vehicle to alert the operator. The warning indicator may provide an audible, visual, and/or tactile indication. Remedial action may also include sending information logged or a warning indicator to a remote location via a communications system 68. Additional remedial action initiated by data acquisition system or controller includes derating the turbo charger, derating the engine connected to the turbo charger, restricting the horsepower production of the engine, restricting the pressurized flow supplied to the compressor, or a complete shutdown of the turbo charger or engine.

For example, in a rail vehicle (FIG. 5), if the compressor wheel deviates from its intended wheel path and contacts the sacrificial wire loop in the clearance, the turbo machine system would receive a signal from detector indicating that the compressor wheel in the turbo charger has begun to rub or is on its way to rubbing which will eventually result in bearing failure and charged air entering the engine crankcase. Engine air entering the crankcase may cause an over pressure shutdown as it typically is a leading indicator of turbo charger damage. To avoid this, upon receiving a signal from the detector, the turbo machine system can derate power to the turbo charger reducing the turbo speed to slow the progression toward failure. This will allow the locomotive to make its own power at the derated threshold allowing it to continue to operate albeit at a slower speed to reach a service shop. To that end, as shown in FIG. 4, the detector may be connected to an engine controller C that derates the turbo charger upon receiving a signal indicating rub from the detector. In addition to avoiding a potential engine failure, controller C may log the rub detection signal from detector to help a service team locate the root cause of a crankcase over pressure shutdown. Often in the case of a crankcase over pressure shutdown or complete failure, the cause is not known once the locomotive arrives at the shop. The presence of a rub indication from the detector before or during the shutdown or failure would indicate that the compressor wheel deviated its intended wheel path.

In one embodiment, remedial action includes communicating with a remote system via a communications system. A communications system may include a radio and an antenna for transmitting and receiving voice and data messages. For example, data communications may be between the vehicle system and a control center of a railroad, another locomotive, a satellite, and/or a wayside device, such as a railroad switch. For example, the controller may estimate geographic coordinates of the vehicle system using signals from a GPS receiver. As another example, the controller may transmit operational characteristics of the engine and/or auxiliary equipment to the control center via a message transmitted from communications system. In one embodiment, a message may be transmitted to the command center by communications system when a degraded component of the engine or auxiliary equipment is detected and the vehicle system may be scheduled for maintenance.

A request to schedule service may be sent, such as by a message sent via communications system, for example. Further, by sending the potential fault condition and the severity of the potential fault, down-time of vehicle V may be reduced. For example, service may be deferred on vehicle V when the potential fault is of low severity. Down-time may be further reduced by derating power of the engine, such as by adjusting an engine operating parameter based on the diagnosed condition. It may be determined if derating of the engine is enabled. For example, derating the power of the engine may reduce the magnitude of one or more components of the frequency content of the generator data.

To provide more detailed information regarding a condition within a turbo charger, plural detectors may be located about the shroud. In addition, each detector system may include more than one sensor. For example, multiple sacrificial wires having different lengths (FIG. 4) may be used to detect progression of blade instability at the compressor wheel. In the example shown, each sensor has its own circuit. In the example shown, sensor has a longer wire loop 55 that extends further into the clearance to provide earlier detection of a condition. Contact with the second sensor indicates that the contact was deeper into the clearance, and likely is a more serious condition. Using feedback from the plural sensors, the controller initiates remedial action and may vary the type of remedial action based on the feedback. For example, if a longer wire is contacted, minimal remedial action may be taken. If the condition progresses to the shorter wire, the controller may derate the turbo charger or shut the turbo charger down to avoid damage to the compressor wheel or other components.

The compressor wheel has been used as an example. The same detector system can be employed to monitor the turbine wheel or other rotating component.

In an embodiment, a detector includes a sensor configured to detect entry of a portion of a wheel into a portion of a clearance gap and thereby to signify that the wheel has deviated from an intended wheel path. In a further embodiment, the detector includes a power source grounded to a rotating machine and connected to the sensor. In this embodiment, passage of the portion of a wheel by the sensor is sensed by the data acquisition system as a displacement current within the wire loop.

In another embodiment, the sensor includes a wire loop connected to a power source; a resistor connected to the wire loop, and a data acquisition system connected to the resistor. A portion of the wire loop extends into the clearance gap. Contact between a portion of the wheel and the portion of the wire loop is sensed by the data acquisition system as a change in voltage across the resistor. In another embodiment, the power source is grounded to a chassis, wherein passage of a portion of the wheel by the portion of the wire loop is sensed as a displacement current in the wire loop. In another embodiment, contact between the wheel and the wire loop is sensed by the data acquisition system as a change in voltage across the resistor.

In an embodiment, the sensor includes a fiber optic member extending into the clearance gap. A data acquisition system is coupled to the fiber optic member to detect changes in an optical value of the fiber optic member indicative of contact with the portion of the fiber optic member inside the clearance gap.

In another embodiment, the sensor includes plural sacrificial members extending into the clearance gap, where one of the plural sacrificial members extends to a greater extent into the clearance gap than another of the plural sacrificial members.

In another embodiment, the wheel is a compressor wheel in a turbo charger.

According to another embodiment, the sensor is operable to respond to detection of the portion of the wheel entering the clearance gap by generating a signal. According to still another embodiment, upon the sensor detecting entry of the wheel into the clearance gap, a controller initiates a remedial action. The remedial action includes at least one of logging information in a memory, transmitting information via a communications system, derating a turbo charger, reducing a speed of the turbo charger, derating a horsepower of an engine connected to the turbo charger, shutdown of the turbo charger, and shutdown of the engine.

An embodiment includes a method that includes detecting a change in at least one of a voltage and a current through a circuit caused in response to an entry of a portion of a wheel within a clearance gap. In an embodiment, the method further includes connecting a sensor in the circuit and inserting the sensor into the clearance gap. In another embodiment, the method includes detecting a fluctuation in at least one of the voltage and the current within the circuit indicative of contact with the sensor. In another embodiment, the sensor includes a sacrificial wire loop connected to a power source. In a further embodiment, the method includes detecting a determined voltage drop or a short in the circuit indicative of the wheel severing the sacrificial wire loop. In another embodiment, the circuit includes a lead connected to the power source and a ground. Passage of a portion of the wheel past the wire is detected as a displacement current.

In another embodiment, the method includes connecting plural sacrificial members to the circuit and inserting the plural sacrificial members into the clearance gap, and extending the plural sacrificial members at different lengths within the clearance gap to detect the severity of a wheel displacement.

According to another embodiment, upon detecting entry of the wheel into the clearance gap, the method includes initiating remedial action including at least one of logging information in a memory, transmitting information via a communications system, derating a turbo charger, reducing a speed of the turbo charger, derating a horsepower of an engine connected to the turbo charger, shutdown of the turbo charger, and shutdown of the engine.

Another embodiment includes a detector kit including a detector circuit including a wire loop connectable to a power source, a resistor, and a data acquisition system. A portion of the wire loop is extendable through an aperture in a rotating system and into the clearance gap. The data acquisition system detects a voltage drop across the resistor and thereby to determine contact between the wheel and the portion of the wire loop. In a further embodiment, the data acquisition system is connectable to a controller in a vehicle.

In another embodiment, a rotating system includes a turbo charger including a wheel mounted on a shaft. The wheel has at least one blade. A shroud at least partially encloses the wheel, where a clearance gap is defined between the at least one blade and an inner surface of the shroud. The rotating system further includes a sensor configured to detect entry of a portion of the wheel into a portion of the clearance gap. In a further embodiment, the sensor is configured to generate a signal signifying that the wheel has deviated from the intended wheel path. In still another embodiment, the wheel is a compressor wheel. In an embodiment, the turbo machine includes an engine connected to the turbo charger, where the engine powers a vehicle. In an embodiment, the vehicle powered by the engine is a rail vehicle.

In one embodiment, a vehicle system is provided. The vehicle system includes an engine, a generator operatively connected to the engine, a sensor for measuring an electrical parameter associated with the generator during operation, and a controller. The controller includes instructions configured to sample the measured electrical parameter, identify frequency content of the measured electrical parameter, and diagnose a condition of the engine based on the frequency content of the measured electrical parameter.

This written description uses examples to disclose the invention, including the best mode, and also to enable one of ordinary skill in the art to practice the invention, including making and using any devices or systems and performing any incorporated methods. The patentable scope of the invention is defined by the claims, and may include other examples that occurred to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A detector comprising:
a sensor configured to detect entry of a portion of a wheel into a portion of a clearance gap and thereby to signify that the wheel has deviated from an intended wheel path.

2. The detector of claim 1 further comprising a power source grounded to a rotating machine and connected to the sensor, wherein passage of the portion of a wheel by the sensor is sensed by a data acquisition system as a displacement.

3. The detector of claim 1, wherein the sensor includes a wire loop connected to a power source, a resistor connected to the wire loop, and a data acquisition system connected to the resistor, wherein a portion of the wire loop extends into the clearance gap, and wherein contact between a portion of the wheel and the portion of the wire loop is sensed by the data acquisition system as a change in voltage across the resistor.

4. (canceled)

5. The detector of claim 1, wherein the sensor includes a fiber optic member, a portion of the fiber member extending into the clearance gap, and the detector further comprises a data acquisition system coupled to the fiber optic member to detect changes in an optical value of the fiber optic member indicative of contact with the portion of the fiber optic member inside the clearance gap.

6. The detector of claim 1 wherein said sensor includes plural sacrificial members extending into the clearance gap, wherein one of the plural sacrificial members extends to a greater extent into the clearance gap than another of the plural sacri ficial members.

7. The detector of claim 1, wherein the wheel is a compressor wheel in a turbo charger.

8. The detector of claim 1, wherein the sensor is operable to respond to detection of the portion of the wheel entering the clearance gap by generating a signal.

9. The detector of claim 1, wherein upon the sensor detecting entry of the wheel into the clearance gap, a controller is configured to initiate a remedial action.

10. The detector of claim 9, wherein the remedial action includes at least one of logging information in a memory, transmitting information via a communications system, derating a turbo charger, reducing a speed of the turbo charger, derating a horsepower of an engine connected to the turbo charger, shutdown of the turbo charger, and shutdown of the engine.

11. A method comprising:
detecting a change in at least one of a voltage and a current through a circuit caused in response to an entry of a portion of a wheel within a clearance gap.

12. The method of claim 11 further comprising installing a detector onto a turbocharger, wherein the detector includes the circuit, and the circuit includes a sensor, and installing the detector corn rises extending the sensor at least partially into the clearance gap.

13. The method of claim 12 further comprising detecting a fluctuation in at least one of the voltage and the current within the circuit indicative of contact with the sensor.

14. The method of claim 15 further comprising detecting a determined voltage drop voltage or a short in the circuit indicative of the wheel severing the sacrificial wire loop.

15. The method of claim 13, further comprising providing power from a power source to a sacrificial wire loop that is part of the sensor.

16. The method of claim 11 further comprising detecting a passage of a portion of the wheel past a portion of the circuit within the clearance gap as a displacement current.

17. The method of claim 13 further comprising connecting plural sacrificial members to the circuit the plural sacrificial members extending at different lengths within the clearance gap to detect the severity of a wheel displacement.

18. The method of claim 11 further comprising responding to a detection of entry of the wheel into the clearance gap by initiating a remedial action including at least one of: logging information in a memory, transmitting information via a communications system, derating a turbo charger, reducing a speed of the turbo charger, derating a horsepower of an engine connected to the turbo charger, shutdown of the turbo charger, and shutdown of the engine.

19. A detector kit comprising:
a detector circuit comprising a wire loop connectable to a power source, a resistor, and a data acquisition system; and
a portion of the wire loop is extendable through an aperture in a rotating system and into a clearance gap, and is configured to drop voltage across the resistor in response to contact between a wheel and the portion of the wire loop,
the data acquisition system is configured to detect a voltage drop across the resistor and thereby to determine contact between the wheel and the portion of the wire loop.

20. The detector kit of claim 19, wherein the data acquisition system is connectable to a controller in a vehicle.

21. A rotating system comprising:
a turbo charger including a wheel mounted on a shaft, the wheel having at least one blade; a shroud at least partially enclosing the wheel, a clearance gap between the at least one blade and an inner surface of the shroud; and
a sensor configured to detect entry of a portion of the wheel into a portion of the clearance gap.

22. The system of claim 21, wherein the sensor is further configured to generate a signal signifying that the wheel has deviated from an intended wheel path.

23. The system of claim 22 wherein the wheel is a compressor wheel.

24. The system of claim 22 further comprising an engine connected to the turbo charger, wherein the engine powers a vehicle.

25. The system of claim 24, wherein the vehicle is a rail vehicle.
